(19) United States
(12) Patent Application Publication
(10) Pub. No.: US 2026/0144007 A1
(43) Pub. Date: May 21, 2026

(54) Method and Device for Separating a Semiconductor Component From a Carrier

(71) Applicant: Pac Tech - Packaging Technologies GmbH, Nauen (DE)

(72) Inventors: Matthias Fettke, Berlin (DE); Andrej Kolbasow, Paulinenaue (DE)

(21) Appl. No.: 18/704,843

(22) PCT Filed: Aug. 28, 2023
(86) PCT No.: PCT/EP2023/073533

§ 371 Date: Apr. 25, 2024

(30) Foreign Application Priority Data
Aug. 31, 2022 (DE) 10 2022 121 966.6

(51) Int. Cl. H10P 72/70

(52) U.S. Cl. CPC H10P 72/744; H10P 72/7412

(57) ABSTRACT

A method for separating a semiconductor component from a carrier, the semiconductor component being held in a material-bonded manner in a connection plane on a carrier by a metalliferous connective agent. The connective agent is liquified and the semiconductor component is taken hold of by a holding tool. The holding tool is oscillated. The holding tool is displaced and the semiconductor component is separated from the carrier. Furthermore, a device for separating a semiconductor component held in a material-bonded manner on a carrier by a connective agent, in which the device comprises a holding tool and at least one drive.

### CROSS-REFERENCE TO RELATED APPLICATION

This application represents the U.S. national stage entry of International Application No. PCT/EP2023/073533 filed Aug. 28, 2023, which claims priority to German Patent Application No. 10 2022 121 966.6 filed Aug. 31, 2022, the disclosure of which is incorporated herein by reference in its entirety for all purposes.

### TECHNICAL FIELD

This disclosure relates to a method for separating a semiconductor component from a carrier and to a device for separating a semiconductor component from a carrier.

### BACKGROUND

Semiconductor components are typically applied in a material-bonded manner on the carrier via a metalliferous connective agent in order to obtain a semiconductor device. On the one hand, the metalliferous connective agent holds the semiconductor component on the carrier and, on the other hand, conducts the electric current required for operating the semiconductor component. In particular the waste materials yielded during the production of semiconductor components cause problems from an ecological point of view. Due to the progressing digitalization in all areas of life, which further increases the demand for semiconductor devices, the scarcity of resources resulting therefrom and the increasing consciousness regarding humanity's influence on the environment, the repurposing, the recycling and/or the repair of installed semiconductor components, in particular semiconductor chips, and semiconductor devices have moved into greater and greater focus. For this purpose, it is necessary to remove defective semiconductor components from a carrier in order to exchange them with functioning components, making it possible to continue to use the device formed from the semiconductor components. Additionally, a still functioning semiconductor component can be separated from the old semiconductor device to find new use in a new semiconductor device when the old semiconductor device is defective and/or outdated. This, however, is only possible when the removal takes place in a manner which prevents damage to other elements of the semiconductor device and/or to the semiconductor component itself.

However, the issue is that semiconductor components and/or the carriers are sensitive and are destroyed in particular when applying too much mechanical force. In spite of this, a certain amount of force is required to overcome the cohesive and adhesive forces of the connective agent, even after its fusion, the cohesive and adhesive forces being higher than the mechanical load threshold of the semiconductor components and/or the carriers. For this reason, a simple separation by lifting the semiconductor component carries the risk of destroying the semiconductor component, the carrier or, in the worst case, the entire semiconductor device.

### SUMMARY

Consequently, a large demand exists for a method and a device which both enable separating a semiconductor component, which is connected to the carrier in a material-bonded manner, from the carrier without destroying either object. This object is attained in a surprisingly simple yet effective manner by a method as disclosed herein and by a device as disclosed herein.

According to one aspect of this disclosure, a method for separating a semiconductor component from a carrier is proposed, the semiconductor component being held in a material-bonded manner in a connection plane on a carrier by a metalliferous connective agent, the method comprising the following steps:
a. liquefying the connective agent and taking hold of the semiconductor component by a holding tool;
b. oscillating the holding tool; and
c. displacing the holding tool and separating the semiconductor chip from the carrier.

In the scope of the disclosure, it has been found that semiconductor components are held in a material-bonded manner on a carrier, the material-bonded connection having been yielded as a rule by multiple targeted insertions of a sphere consisting of the metalliferous connective agent. In this context, the arrangement has taken place in a plane which now forms the connection plane. If this connective agent is liquefied, the cohesive and adhesive forces are the larger, the larger the targeted connections formed by the spheres are. These cohesive and adhesive forces need to be overcome in order to enable a separation of the semiconductor component from the carrier. It has further been found that the cohesive and adhesive forces are so great that the tensile forces required for overcoming the cohesive and adhesive forces are so great during a generic lifting that a non-destructive separation of the semiconductor component from the carrier guaranteed cannot be ensured. The adhesion causes the liquefied connective agent to take on a spheroid form which is flattened in the border areas to the carrier and to the semiconductor component. The cohesion causes the molecules to cohere in the liquefied connective agent. If the semiconductor component together with the holding tool is now oscillated, the inertia causes an oscillation of the liquefied connective agent which transcends the oscillation movement, while the adhesion continues to cause the liquefied connective agent to remain at the border areas to the carrier and to the semiconductor component. Owing to this, the connective agent is forced from its natural spheroid form to a slimmer form, whereby the cohesive forces are reduced. Particularly preferably, a constriction arises in the liquefied connective agent, the constriction optimally being reduced by the oscillation insofar that it divides the liquefied connective agent into two parts. One part of the liquefied connective agent adheres to the semiconductor component, while the other part adheres to the carrier. The cohesive forces between the two parts of the liquefied connective agent no longer exist in this state; the semiconductor component can be easily displaced together with the holding tool, and the semiconductor component can be separated from the carrier. A complete separation of the connective agent into two parts is not strictly necessary for the functionality of the method, as the slimming caused by the oscillation and the inertia can reduce the cohesive and adhesive forces insofar that a displacement of the holding tool and a separation of the semiconductor component are already possible non-destructively. The liquefied connective agent is divided into two parts at the latest upon displacing the semiconductor tool and upon separating the semiconductor component. Theoretically, it is also possible that the separation takes place via a complete removal of the entire liquefied connective agent from the carrier or from the semiconductor component. This takes place when the cohesive forces are greater than the adhesive forces to one of the border surfaces. In practice, however, it has proven that, as a rule, this is not the case.

In step a., the connective agent is liquefied to allow a separation. As long as the connective agent is solid, the material-bonded connection between the connective agent and the carrier or between the connective agent and the semiconductor component persists. Equally, the cohesive forces in a solid body are significantly greater than the cohesive forces in a liquid. The liquefaction is thus a first significant reduction of the cohesive forces. Taking hold of the semiconductor component via the holding tool, which also takes place in step a., allows the semiconductor component to be moved by the holding tool. In doing so, it is necessary to be able to transfer a mechanical force from the holding tool to the semiconductor component. For this purpose, the holding tool is brought into contact with the semiconductor component to take hold of the same.

In step b., the holding tool is oscillated. This means that the holding tool executes a periodic motion, in particular a linear motion or a circular motion. Since the holding tool has taken hold of the semiconductor component, the motion is transferred to the semiconductor component so that the semiconductor also executes a, preferably the same, periodic motion. Furthermore, the periodic motion of the semiconductor component is transferred at least partially to the liquefied connective agent via the cohesive and adhesive forces. In doing so, the cohesive and adhesive forces are reduced via the mechanisms described above; preferably, the connective agent is divided into two parts.

In step c., the holding tool is displaced. This means it changes its position via movement. Preferably, it is displaced away from the carrier. In doing so, the semiconductor component still held by the holding tool is also displaced. Should a connection formed by the connective agent still exist between the semiconductor component and the connective agent, the cohesive and adhesive forces are reduced insofar that they can be overcome by displacing the semiconductor component, without risking mechanically overstressing the semiconductor component and/or the carrier. Finally, the semiconductor component and the carrier are separated.

The term “semiconductor component” refers to a component which comprises at least one semiconductor material layer. In particular, a semiconductor chip is a semiconductor component.

The term “carrier” refers to a component on which at least one semiconductor component is applied in a material-bonded manner and which finds itself in contact with the semiconductor component by conducting electric current. In particular, a printed circuit board is a carrier.

The term “metalliferous connective agent” refers to a metalliferous substance for forming a conductive connection between the semiconductor component and the carrier. Possible connective agents are solder, metalliferous adhesive, sinter paste and/or metalliferous ink. The process of liquefying the connective agent has to be adapted to the connective agent as required.

By the method according to the disclosure, it is possible to non-destructively remove semiconductor components from the carrier. Non-destruction involves the semiconductor component and the carrier as well as any other elements on the carrier. This allows the renewed use of the semiconductor component and/or the carrier in a different device or a device possibly serving a different purpose after they have been separated. In particular, it is possible to repair the carrier by removing and replacing a defective semiconductor component. An upgrade by removing an outdated semiconductor component and replacing it with a faster and/or more powerful semiconductor component is also conceivable. Furthermore, the separation can serve the repurposing of the material forming the semiconductor component and/or the carrier. In this manner, the necessity of producing new semiconductor components and/or carriers is reduced, whereby ultimately the environment and resources are protected.

Advantageous embodiments, which can be realized individually or in combination with each other, are presented in the dependent claims.

It is conceivable for the taking hold in step a. to take place via suctioning, adhesion and/or clamping.

The term “suctioning” refers to the generation of a locally limited negative pressure at the surface of the semiconductor component. This technique is easily controllable and can be applied to large surfaces of the semiconductor component with a correspondingly designed tool, which is preferably adapted or adaptable to the size of the semiconductor components. This yields an even force effect on large surfaces with reference to the semiconductor component, thus producing an even mechanical load on large surfaces of the semiconductor component. This prevents a high and locally limited overstressing via mechanical tension.

The term “adhesion” refers to the effect of adhesive forces without the use of connective agents or supported by weakly adhesive connective agents, said forces acting on the surface of the semiconductor component via a correspondingly designed element, such as a film. Even with adhesion, an even force effect on large surfaces of the semiconductor component is yielded, meaning the mechanical tension is evenly distributed. Another advantage of adhesion is that the taking hold does not depend on an exterior power supply.

Both the suctioning and the adhesion allow lateral compensational movements of the semiconductor component when the cohesive and adhesive forces are too large, and there is a risk of overstressing the semiconductor component.

The term “clamping” refers to the grabbing of the semiconductor component by a two or multi-legged tool, whose legs fixatingly act on the semiconductor component in the opposite direction. The advantage of clamping is that the oscillation can be safely and entirely transferred to the semiconductor component. A shifting or displacing of the semiconductor component in relation to the receiving tool is effectively prevented with clamping. In this manner, a large portion, preferably the entirety, of the oscillating movement can be transferred to the connective agent.

In another embodiment, it is conceivable for the liquefaction in step a. to take place via heating. In the scope of the disclosure, it has been found that most connective agents become liquid under the influence of heat; this takes place at low enough temperatures which ensure that the semiconductor component or the carrier is not damaged. In this context, it is conceivable for the connective agent to be indirectly heated by heating the semiconductor component and/or the carrier and by conducting the heat to the connective agent via the semiconductor component and/or the carrier. In order to preclude damage to the semiconductor component and/or to the carrier via arising toxic substances, e.g., via the oxidation of the connective agent, the heating temperature has to be adapted to the connective agent used in that instance as required.

In another embodiment, it is conceivable for the heating to take place via directly or indirectly subjecting the connective agent to laser radiation. As laser radiation is characterized in particular by a sharp focusing of beams, laser radiation can be used in an easy and targeted manner. This allows a targeted and thus particularly efficient heating of the connective agent, wherein adjacent areas of the semiconductor device, in particular adjacent semiconductor components, their connective agents and/or other elements disposed on the carrier are not subjected to the heat or are subjected to it only to a small degree.

The term “laser radiation” refers to electromagnetic radiation, which is narrowband, in particular single-mode, and is characterized by a sharp focusing and a large coherence length of the beam. The wavelength has values between 100 nm to 30 μm.

In addition, it is conceivable for the oscillation in step b. to take place parallel to the connection plane. In this manner, a particularly high degree of the inertia forces acts on a constriction of the connective agent, whereby the cohesive forces are reduced and the effect of the constriction causing the separation can be yielded particularly effectively. Equally, the risk of the semiconductor component bumping vertically against the carrier because of the oscillation and/or of the mechanical tension of the cohesive and adhesive forces too strongly stressing the semiconductor component, should the semiconductor component be removed too far vertically from the carrier, is reduced.

It is further conceivable for the oscillation in step b. to take place at a frequency of 10 kHz to 1 MHz. In the scope of the disclosure, it has been found that an oscillation of the liquefied connective agent by a frequency in the vicinity, particularly preferably by the inherent frequency of the connective agent, oscillates the connective agent at a maximal amplitude. In this manner, the desired effect of the constriction of the connective agent can be yielded to a particularly high degree. It has proven that the inherent frequency, which depends on the material used and the size of the nearly spheroid connective agent, seems to range from 10 kHz to 1 MHz, the best results being achieved in this frequency range.

Moreover, it is conceivable for the oscillation in step b. to be generated by rotating an unbalance and/or by changing the voltage at a vibrating quartz and/or at a coil. These methods are easily controllable methods of generating oscillation which allow an oscillation to an adequate degree and at a suitable frequency. In particular, the frequency of the oscillation can be freely set at least in sections. The change in voltage at the coil causes a magnetic field, which acts on a corresponding agent attracted and/or repelled by a magnetic field. The change in voltage is preferably periodic, in particular a sine-shaped alternating voltage or a pulsed direct voltage.

In an embodiment, it is conceivable for the oscillation of the holding tool to be continued in step c, in particular upon displacement. If the liquefied connective agent is not further divided in step b., the reduction of the cohesive forces is maintained, in particular via the constriction, in step. c. It is then possible to displace the holding tool risk-free without the carrier and/or semiconductor component being overstressed.

Moreover, it is conceivable for the displacement in step c. to take place vertically to the connection plane. In this manner, semiconductor components, which are placed centrally on the carrier and are possibly laterally blocked in the connection plane by other elements of the carrier, in particular other semiconductor components, can still be removed without bumping together.

It is presumed that the definitions and/or explanations of the terms described above apply to all aspects described in this description in the following, provided no other statements have been made in this regard.

The disclosure further proposes a device for separating a semiconductor component held in a material-bonded manner on a carrier by a connective agent, the device comprising a holding tool and at least one drive, the holding tool having a holding plane. The device is characterized in that the device comprises an oscillator. By this device, the method according to the disclosure can be executed and the advantages pertaining to the method can be achieved. This means that the device is suitable for non-destructively separating the semiconductor component from the carrier after the connective agent has been liquefied owing to the physical processes expounded above for reducing the cohesive and adhesive forces. This makes it possible to repair, upgrade, repurpose and/or recycle the carrier and/or the semiconductor component. In which manner the connective agent is liquefied is generally arbitrary; however it is preferably conceivable for the device to have an element for liquefaction, as described elsewhere as an example. To execute the method according to the disclosure, the connective agent is liquefied, and the holding tool takes hold of the semiconductor component in the holding plane, preferably via the drive establishing contact between the holding tool and the semiconductor component. Subsequently, the oscillator oscillates the holding tool. The drive displaces the holding tool with the semiconductor component and thus separates the semiconductor component from the carrier. In this context, the holding plane is parallel to the connection plane of the method according to the disclosure.

It is conceivable for the holding tool of the device to comprise a suction head, an adhesion film and/or grippers. These tools are suitable for yielding the types of taking hold described in connection with the method, namely suction, adhesion and/or clamping, including the advantages pertaining thereto. The suction head is particularly preferably an opening which is connected to a vacuum pump using an adequate element, such as a hose, the vacuum pump generating a negative pressure at the suction head. Adhesion films are films which establish adhesion on smooth surfaces as a result of adhesive forces. Adhesion films can be produced without glue or by adding and/or coating suitable weak glues. The skilled person is familiar with suitable materials. Grippers are a two or multi-leg tool in which the legs act fixatingly on the semiconductor component in the opposite direction.

Grippers and/or a suction head have the advantage that the holding effect of the holding tool can be released in a mechanical manner. The suction head and the adhesion film have the advantage of adhering on large surfaces and the holding force being adjustable in such a manner that the semiconductor component can shift at the holding tool upon a mechanical load threshold being exceeded by the oscillation. This prevents a mechanical overstressing of the semiconductor component. The grippers can fully transfer the movement of the holding tool to the semiconductor component.

In another embodiment, it is conceivable for the device to comprise a heat source. By the heat source, the connective agent can be liquefied as intended. In doing so, the heat source can directly affect the connective agent or indirectly affect the semiconductor component and/or the carrier, the heat being conducted to the connective agent via the semiconductor component and/or the carrier.

In another embodiment, the heat source has a laser. A laser emits focused coherent electromagnetic radiation, meaning a locally limited area can be heated in a targeted manner. Since the semiconductor components are minuscule, this enables the targeted, direct or indirect, heating of the connective agent, adjacent elements, in particular adjacent semiconductor components disposed on the carrier, not being influenced or being influenced, in particular heated, only to a small degree.

The term “laser” refers to an apparatus which emits narrowband, in particular single-mode, electromagnetic radiation having a sharp focusing and a coherence length of the beam at a wavelength between 100 nm and 30 μm. In particular, a maser is also comprised.

In another embodiment, it is conceivable for the device to comprise a beam channel, the beam channel beginning at the laser and ending at the holding tool. A beam channel is a component suitable for conducting electromagnetic radiation over a longer distance. Particularly preferably, the beam channel is an optical waveguide. The arrangement of a beam channel makes it possible to attach the laser at a fixed position and to conduct the emitted radiation to the holding tool by the beam channel. This can sufficiently cool the laser, for example, and the power supply of the laser is ensured. In another embodiment, it is conceivable for the beam channel to be hollow, the laser radiation being conducted in the hollow area of the laser channel and/or in the jacket of the beam channel. The beam channel is preferably shaped like a hose. The hollow area allows forming a negative pressure and/or a vacuum, meaning the holding tool can be designed as a suction head. This allows designing the device, in particular the holding tool, so as to be small, narrow and compact.

Moreover, it is conceivable for the oscillator to have an oscillation direction, the oscillation direction being parallel to the holding plane. In this manner, the semiconductor component is oscillated in a plane parallel to the connection plane, thus attaining the advantages pertaining thereto. In particular, the cohesive and adhesive forces are reduced particularly efficiently, and the risk of the semiconductor component vertically bumping against the carrier because of the oscillation and/or the mechanical tension of the cohesive and adhesive forces overstressing the semiconductor component is minimized.

In another embodiment, it is conceivable for the oscillator to have an oscillation range of 100 kHz to 1 MHz. The connective agent has an inherent frequency, which seems to be in this range. An oscillation in this frequency range leads to a particularly effective and reliable division of the connective agent, the division minimizing, in particular eliminating, the adhesive and cohesive forces which act between the carrier and the semiconductor component via the connective agent. The holding tool can thus be displaced with the semiconductor component without risk.

Moreover, it is conceivable for the oscillator to comprise an unbalance motor, a quartz oscillator and/or oscillating magnets, in particular an oscillator coil. In an unbalance motor, an unbalance is made to rotate, meaning a periodic deflection occurs. In a quartz oscillator, a changing electric voltage is applied to an oscillating quartz. An oscillating quartz is a quartz which experiences deformation owing to the piezoelectric effect upon a change in voltage. An oscillating magnet is a component which comprises a magnetically deflectable mass, an electric coil and an attenuation element. To produce the oscillation, a changing electric voltage is applied to the electric coil, which generates a changing magnetic field. The magnetic field deflects the magnetically deflectable mass against the attenuation. The deflection is temporally variable owing to the change of the magnetic field, whereby the deflectable mass oscillates. Preferably, the changing electric voltage is a sine-shaped alternating voltage or a pulsed direct voltage.

Moreover, it is conceivable for the drive of the device to be a linear drive and for the holding tool to be vertically displaceable to the holding plane by the drive. The advantage of the vertical displaceability is that the semiconductor component can be removed from the carrier, without running the risk of it bumping against other elements disposed on the carrier. It is also conceivable for the device to comprise a second drive and/or a third drive, in particular a second linear drive and/or a third linear drive, for the vertical displaceability aside from the first drive, the second drive and/or the third drive displacing the holding tool parallel to the holding plane in a spatial direction each. Consequently, the holding tool can be positioned above the semiconductor component by the second drive and/or the third drive and can subsequently be lowered onto the semiconductor component for taking hold of the same by the first drive. After the semiconductor component has been separated from the carrier by the first drive, the lifted semiconductor component can be moved laterally to a deposit location by the second drive and/or the third drive. Particularly preferably, the device comprises a biaxial robot arm at whose freely movable end the holding tool and the oscillator are disposed.

Moreover, it is conceivable for the oscillator to be spaced apart from the holding tool. Particularly preferably, it is spaced apart 5 mm to 20 mm from the holding tool. As a rule, the oscillator is disposed on the exterior of the device and its dimensions are therefore wider than the holding tool itself. The wider dimensions of the oscillator carry the risk of the oscillator bumping against other elements disposed on the carrier and thus damaging these when displacing the holding tool and/or upon oscillation. A spacing to the holding tool prevents the oscillator from bumping against other elements. Nevertheless, the oscillator should be disposed as closely to the holding tool as possible so that the holding tool is oscillated as intended.

Further details, features and advantages of the invention are yielded from the following description of the preferred exemplary embodiments in connection with the dependent claims. In this context, the respective features can be realized on their own or in combination with each other. The invention is not limited to the exemplary embodiments. The exemplary embodiments are shown schematically in the figures. The same reference numerals in the individual figures refer to the same elements or elements having the same function or corresponding to one another regarding their functionality.

### BRIEF DESCRIPTION OF THE FIGURES

FIG. 1 shows an embodiment of a device according to the disclosure.

FIGS. 2A to 2C show an embodiment of a method according to the disclosure by use of the device according to the disclosure.

### DETAILED DESCRIPTION

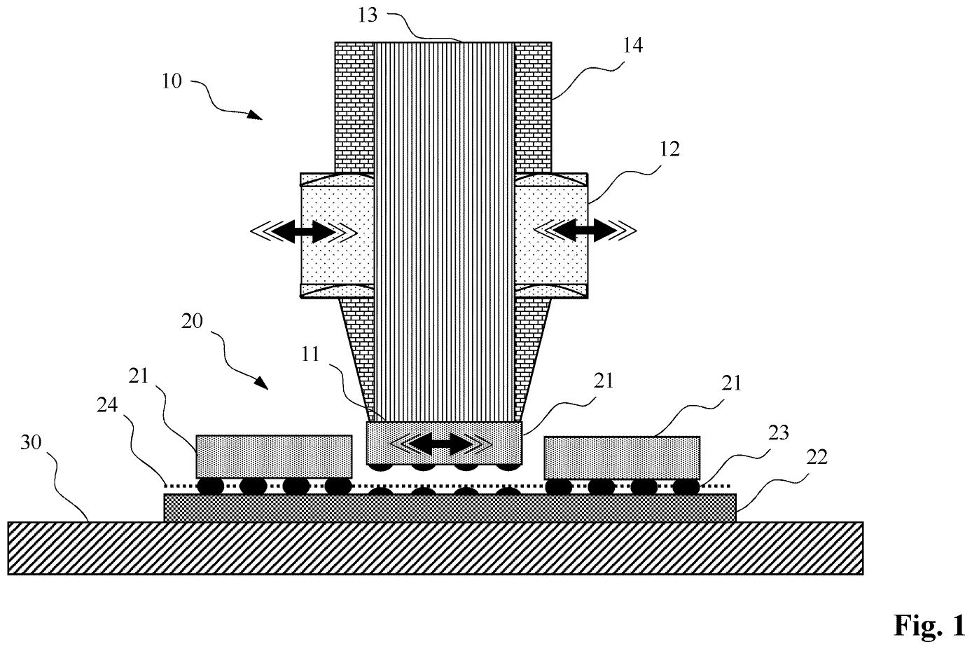

FIG. 1 shows an embodiment of a device 10 according to the disclosure. Device 10 comprises a holding tool 11, which is a suction head in the shown embodiment. An oscillator 12 is spaced apart from holding tool 11. Oscillator 12 is disposed around a beam path 13, beam path 13 being hollow. Beam path 13 conducts laser radiation of a laser (not shown) to holding tool 11. The hollow design makes it possible to generate a negative pressure at holding tool 11 in order to produce the suctioning effect of the suction head in this manner. Beam path 13 is further enclosed by a casing 14. As is further discernable in FIG. 1, holding tool 11 holds a semiconductor component 21. Semiconductor component 21, which is held by holding tool 11, has already been separated from a carrier 22. Further evidently discernable, oscillator 12 is wider than the space intended on carrier 22 for semiconductor component 21 held by holding tool 11. By spacing oscillator 12 apart from holding tool 11, a bumping of oscillator 12 against semiconductor components 21 remaining on carrier 22 is prevented, both remaining semiconductor components 21 being connected to carrier 22 via spheroid connective agents 23 applied in a targeted manner. Connective agents 23 are disposed in a connection plane 24 in this context. As is further discernable in FIG. 1, connective agents 23, which are applied in a targeted manner and have held semiconductor component 21 held by holding tool 11 on carrier 22, have been divided into two parts, one part adhering at semiconductor component 21 held by holding tool 11 and the other part remaining on carrier 22. Carrier 22 is placed on a work surface 30 for better handling. In order to be able to divide connective agents 23 and to overcome the cohesive and adhesive forces, which hold semiconductor components 21 connected to carrier 22, in this manner, oscillator 12 oscillates device 10 and thus holding tool 11 and semiconductor component 21 held by holding tool 11.

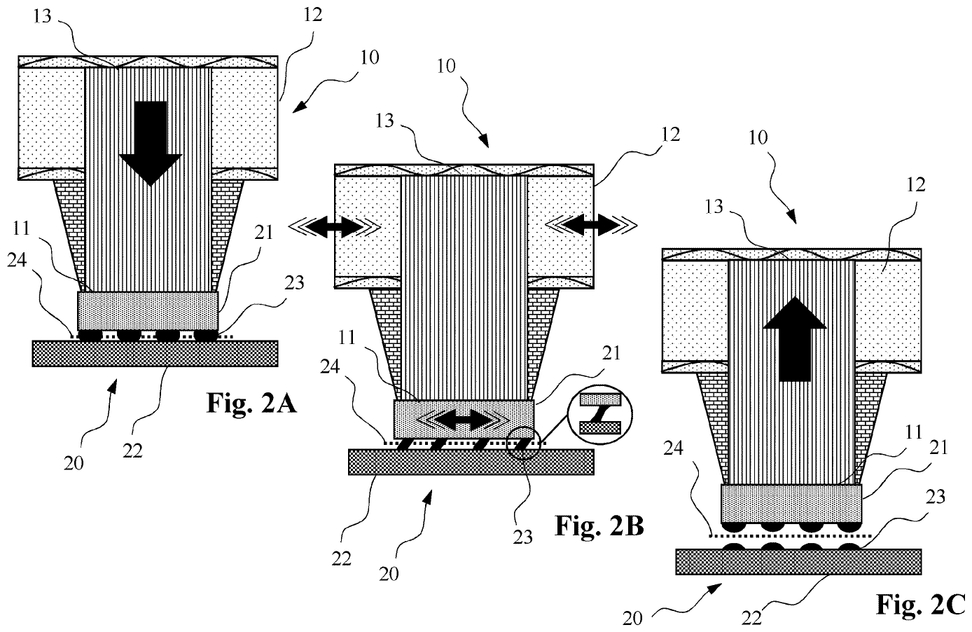

The figures FIG. 2A to FIG. 2C show an embodiment of the method according to the disclosure by use of device 10 according to the disclosure and shown in FIG. 1.

In FIG. 2A, a semiconductor component 21 connected to a carrier 22 in a material-bonded manner via a spheroid connective agent 23 disposed in a targeted manner in a connection plane 24 is taken hold of by a holding tool 11. This takes place by device 10 being displaced vertically to semiconductor component 21 and by a negative pressure being applied at holding tool 11, which is configured as a suction head. In other words, semiconductor component 21 is suctioned by holding tool 11. Simultaneously, connective agent 23 is heated by conducting laser radiation to semiconductor component 21 through a beam channel 13. The laser radiation heats semiconductor component 21 which conducts the heat to connective agent 23. The heat liquefies connective agent 23.

FIG. 2B shows the oscillation of holding tool 11 by oscillator 12. The oscillation takes place parallel to connection plane 24. In this context, semiconductor component 21 also oscillates. It can be seen in FIG. 2B that connective agent 23 experiences constriction due to inertia. Due to this constriction, cohesive and adhesive forces, which act within connective agent 23 and between connective agent 23 and carrier 22 and/or between connective agent 23 and semiconductor component 21, are reduced.

In FIG. 2C, it is discernable that connective agents 23 have each been divided into two parts via the oscillation and the constriction, one part remaining at carrier 22 and the other part adhering to semiconductor component 21. Due to this division of connective agent 23, the cohesive and adhesive forces, which held semiconductor component 21 at carrier 22 via connective agent 23, have been overcome. Semiconductor component 21 has been separated from carrier 22 and can now be entirely removed by vertically displacing holding tool 11.

1. A method for separating a semiconductor component from a carrier, the semiconductor component being held in a material-bonded manner in a connection plane on a carrier by a metalliferous connective agent, the method comprising the following steps:
a. liquefying the connective agent and taking hold of the semiconductor component by a holding tool;
b. oscillating the holding tool; and
c. displacing the holding tool and separating the semiconductor component from the carrier.

2. The method according to claim 1,
wherein the taking hold in step a. takes place via suctioning, adhesion and/or clamping.

3. The method according to claim 1,
wherein the liquefaction in step a. takes place via heating.

4. The method according to claim 3,
wherein the heating takes place via directly or indirectly subjecting the connective agent to laser radiation.

5. The method according to claim 1,
wherein the oscillation in step b. takes place parallel to the connection plane.

6. The method according to claim 1,
wherein the oscillation in step b. takes place at a frequency of 10 kHz to 1 MHz.

7. The method according to claim 1,
wherein the oscillation in step b. is generated by rotating an unbalance and/or by changing the voltage at a vibrating quartz and/or at a coil.

8. The method according to claim 1,
wherein the oscillation of the holding tool is continued in step c.

9. The method according to claim 1,
wherein the displacement in step c. takes place vertically to the connection plane.

10. A device for separating a semiconductor component held in a material-bonded manner on a carrier by a connective agent, the device comprising a holding tool and at least one drive, the holding tool having a holding plane,
wherein
the device comprises an oscillator.

11. The device according to claim 10,
wherein
the holding tool comprises a suction head, an adhesion film and/or grippers.

12. The device according to claim 10,
wherein
the device comprises a heat source.

13. The device according to claim 12,
wherein
the heat source has a laser.

14. The device according to claim 13,
wherein
the device comprises a beam channel, the beam channel beginning at the laser and ending at the holding tool.

15. The device according to claim 10,
wherein
the oscillator comprises an oscillation direction, the oscillation direction being oriented parallel to the holding plane.

16. The device according to claim 10,
wherein
the oscillator has an oscillation range of 10 kHz to 1 MHz.

17. The device according to claim 10,
wherein
the oscillator comprises an unbalance motor, a quartz oscillator and/or oscillating magnets, in particular an oscillator coil.

18. The device according to claim 10,
wherein
the drive is a linear drive and in that the holding tool is vertically displaceable by the drive.

19. The device according to claim 10,
wherein
the oscillator is spaced apart from the holding tool.
